(19) United States
(12) Patent Application Publication
(10) Pub. No.: US 2014/0041712 A1
(43) Pub. Date: Feb. 13, 2014

(54) POWER GENERATOR

(71) Applicants: Shoji Mima, Ehime (JP); Takahiro Seike, Ibaraki (JP)

(72) Inventors: Shoji Mima, Ehime (JP); Takahiro Seike, Ibaraki (JP)

(73) Assignee: SUMITOMO CHEMCIAL COMPANY, LIMITED, Chuo-ku, Tokyo (JP)

(21) Appl. No.: 13/880,459

(22) PCT Filed: Oct. 18, 2011
(86) PCT No.: PCT/JP2011/073954

§ 371 Date: Oct. 30, 2013

(30) Foreign Application Priority Data
Oct. 26, 2010 (JP) 2010-239426

(51) Int. Cl. H01L 51/00; H01L 27/30

(52) U.S. Cl. CPC H01L 51/0005; H01L 27/301
USPC 136/249; 438/61

(57) ABSTRACT

Power generator including a supporting substrate and a plurality of organic photovoltaic cells that are provided on the supporting substrate along a prescribed alignment direction and are serially connected with each other. Each of the organic photovoltaic cells includes a pair of electrodes and an active layer placed between the pair of electrodes. The active layer extends along the prescribed alignment direction s plurality of organic photovoltaic cells. Each of the pair of electrodes has an extending portion that extends to protrude from the active layer into a direction perpendicular to both a thickness direction of the supporting substrate and the alignment direction. One electrode out of the pair of electrodes further has a connecting portion that extends in the alignment direction from the extending portion to the opposite electrode of other organic photovoltaic cell adjacent in the alignment direction and is connected to the opposite electrode.

### TECHNICAL FIELD

The present invention relates to a power generator and a method for manufacturing the same.

### BACKGROUND ART

An organic photovoltaic cell comprises a pair of electrodes (an anode and a cathode) and an active layer placed between the electrodes. An organic substance is used as a photovoltaic material contained in the active layer. As a power generator utilizing the organic photovoltaic cell, for example, for enhancing the output voltage a power generator in which a plurality of organic photovoltaic cells are serially connected with each other has been studied (for example, see Non Patent Document 1).

FIG. 9A and FIG. 9B are views schematically illustrating a power generator in which a plurality (three cells in FIG. 9A and FIG. 9B) of organic photovoltaic cells are serially connected with each other. FIG. 9A is a schematic plan view of a power generator. FIG. 9B is a schematic cross-sectional view of a power generator taken along a 9B-9B chain line in FIG. 9A.

A power generator 2 illustrated in FIG. 9A and FIG. 9B includes three organic photovoltaic cells 1. These three organic photovoltaic cells 1 are serially arranged in a prescribed direction along the alignment direction X on a supporting substrate 3 and are electrically connected with each other. As described above, each of the organic photovoltaic cells 1 comprises a pair of electrodes and an active layer 6 placed between the pair of electrodes. Hereinafter, one electrode arranged nearer to the supporting substrate 3 out of the pair of electrodes is called a first electrode 4 and the other electrode arranged parted from the supporting substrate 3 farther away than the first electrode 4 is called a second electrode 5. Any one electrode among these first electrode 4 and second electrode 5 functions as an anode and the other electrode functions as a cathode. By taking into consideration the device characteristics and easiness of a step, for example, not only the active layer 6, but also a prescribed layer different from the active layer 6 may be placed between the first electrode 4 and the second electrode 5.

A plurality of first electrodes 4 of a plurality of organic photovoltaic cells 1 are discretely arranged at a prescribed interval in the alignment direction X as illustrated in FIG. 9A and FIG. 9B. Therefore, a plurality of first electrodes 4 are not electrically connected with each other. In the same manner, a plurality of second electrodes 5 of a plurality of organic photovoltaic cells 1 are discretely arranged at a prescribed interval in the alignment direction X. Therefore, a plurality of second electrodes 5 are not electrically connected with each other. Thus, the plurality of first electrodes 4 are not electrically connected with each other and the plurality of second electrodes 5 are not electrically connected with each other.

In a plurality of organic photovoltaic cells 1 adjacent to each other in the alignment direction X, the first electrode 4 of one organic photovoltaic cell and the second electrode 5 of another organic photovoltaic cell adjacent to the one organic photovoltaic cell in the alignment direction X are physically connected with each other, so that they are electrically connected with each other. By this connection, a plurality of organic photovoltaic cells 1 are serially connected with each other. Specifically, the first electrode 4 of one organic photovoltaic cell 1 is formed to extend to a position at which the end of the first electrode 4 in one side (hereinafter, may be called “left end”) of the alignment direction X (hereinafter, “one side of the alignment direction X” may be called “left side” and “the other side of the alignment direction X” may be called “right side”) is overlapped with the end in a right side (hereinafter, may be called “right end”) of the second electrode 5 of another organic photovoltaic cell 1 adjacent to the one organic photovoltaic cell 1 in a left side thereof, and by being physically connected with the first electrode 4 of another organic photovoltaic cell 1 adjacent to the one organic photovoltaic cell 1 in a left side thereof, the first electrode 4 and the second electrode 5 are electrically connected with each other. Thus, a plurality of organic photovoltaic cells 1 are serially connected with each other by electrically connecting the first electrode 4 of one organic photovoltaic cell 1 with the second electrode 5 of another organic photovoltaic cell adjacent to the one organic photovoltaic cell 1 in the alignment direction X.

### RELATED ART DOCUMENTS

### Non Patent Document

Non Patent Document 1: Synthetic Metals 159 (2009) 2358-2361

### DISCLOSURE OF INVENTION

### Problem to be Solved by the Invention

Various methods are available for forming the active layer. For example, if the active layer 6 is formed using a coating method, the active layer 6 is formed by, first, applying an ink containing a material for the active layer 6 to form a film by a prescribed coating method and then solidifying the resultant film.

The following describes steps of manufacturing a plurality of organic photovoltaic cells 1 connected serially with each other as illustrated in FIG. 9A and FIG. 9B by a coating method, referring to FIG. 10A, FIG. 10B, FIG. 10C, and FIG. 10D. FIG. 10A, FIG. 10B, FIG. 100, and FIG. 10D are cross-sectional views schematically illustrating, in the same manner as in FIG. 9B, steps of forming a plurality of organic photovoltaic cells 1 illustrated in FIG. 9A and FIG. 9B.

First, three first electrodes 4 are discretely formed with a prescribed interval in the alignment direction X on the supporting substrate 3 as illustrated in FIG. 10A. For example, first, a conductive thin film is formed by a sputtering method and further, the conductive thin film is subjected to a photolithography step and a patterning step, so that the first electrode 4 can be discretely formed.

Next, an ink containing a material for the active layer 6 is applied onto the supporting substrate 3 by a prescribed coating method as illustrated in FIG. 10B. Generally, with a coating method, it is difficult to selectively apply an ink only to a target region to form a pattern of an ink. Therefore, an ink is also applied onto a region where the application is not necessary such as a region between a plurality of first electrodes 4 and a partial region of the first electrode 4.

After the ink is applied, a step is necessary for removing a part of the applied ink from a region where the application is not necessary as illustrated in FIG. 10C. The step of removing the ink is performed, for example, by wiping off the applied ink using a cloth or a cotton swab containing a solvent capable of dissolving the applied ink.

Next, for example, the coating film is solidified to form the active layer 6 by heating the coating film of the applied ink as illustrated in FIG. 10D. Then, for example, by a vapor deposition method, the second electrode 5 is pattern-formed. The second electrode 5 is formed from a position at which the second electrode 5 is overlapped with one of the adjacent first electrodes 4 to a position at which the second electrode 5 is overlapped with a part of the other first electrode 4. Thus, a plurality of organic photovoltaic cells 1 connected serially with each other are formed.

As described above, if the active layer 6 is formed using a coating method, a step is necessary for removing a part of the once applied ink. Therefore, there is a problem that the number of steps increases.

In addition, because the active layer 6 is generally degraded by being exposed to the atmosphere, it is preferred to shorten the duration time which the active layer 6 is exposed to the atmosphere as much as possible in a step of forming the organic photovoltaic cell 1. It is, therefore, necessary that after the ink is applied, an electrode or the like covering the active layer is formed as soon as possible.

The method described with reference to FIG. 10A to FIG. 10D requires a step of removing a part of the applied ink. Therefore, the duration time which the active layer 6 is exposed to the atmosphere becomes longer, so that there is such a threatening that the active layer 6 becomes degraded.

The first electrode 4 is formed, for example, by a method capable of forming a fine pattern such as a photolithography step and a patterning step, and vapor deposition with a mask, so that it is possible to make a distance between the adjacent first electrodes 4 extremely small. Meanwhile, by a method for removing a part of the once applied ink, it is generally difficult to wipe off a part of the ink applied in such an extremely small width as the distance between the adjacent first electrodes 4. Therefore, even if the first electrodes 4 are formed so as to make the distance between the first electrodes 4 adjacent to each other becomes extremely small, a part of the ink is removed in a width larger than the distance between the adjacent first electrodes 4, so that there is a problem, arising from the step of removing a part of the once applied ink, that an area capable of being utilized in the power generation among the area of the power generator, that is, a power generating region becomes small.

Accordingly, it is an object of the present invention to provide a power generator capable of being manufactured by a simple coating method requiring no patterning of an active layer and comprising a plurality of organic photovoltaic cells connected serially with each other.

### Means for Solving Problem

The present invention provides [1] to [7] below.

[1] A power generator comprising:

a supporting substrate; and a plurality of organic photovoltaic cells provided on the supporting substrate along a prescribed alignment direction and serially connected with each other, wherein

each of the organic photovoltaic cells comprises a pair of electrodes and an active layer provided between the pair of electrodes,

the active layer extends along the prescribed alignment direction across the plurality of organic photovoltaic cells, when viewed from one side in the thickness direction of the supporting substrate,

each of the pair of electrodes has an extending portion that extends to protrude from the active layer into a direction perpendicular to both the thickness direction of the supporting substrate and the alignment direction, when viewed from one side in the thickness direction of the supporting substrate, and

one electrode of the pair of electrodes further has a connecting portion that extends in the alignment direction from the extending portion to the opposite electrode of another organic photovoltaic cell adjacent in the alignment direction and is connected to the opposite electrode.

[2] The power generator according to above [1], further comprising an auxiliary electrode that is provided to be in contact with one of the pair of electrodes and has a lower sheet resistance than the electrode being in contact within.
[3] The power generator according to above [2], wherein the auxiliary electrode is provided to be in contact with the electrode having a higher sheet resistance out of the pair of electrodes.
[4] The power generator according to any one of above [1] to [3], wherein only the electrode having a lower sheet resistance, out of the pair of electrodes, has the connecting portion.
[5] The power generator according to any one of above [1] to [4], wherein the extending portion has a first extending portion and a second extending portion, the first extending portion extending to protrude from the active layer into one width direction and the second extending portion extending to protrude from the active layer into the other side of the width direction, each when viewed from one side in the thickness direction of the supporting substrate.
[6] A method for manufacturing a power generator comprising a supporting substrate and a plurality of organic photovoltaic cells provided on the supporting substrate along a prescribed alignment direction and serially connected with each other, each of the organic photovoltaic cells comprising a pair of electrodes and an active layer placed between the pair of electrodes, the method comprising the steps of:

forming the pair of electrodes having an extending portion that extends to protrude from the active layer into a direction perpendicular to a thickness direction of the supporting substrate and the alignment direction, when viewed from one side in the thickness direction of the supporting substrate, one electrode of the pair of electrodes further having a connecting portion extending in the alignment direction from the extending portion to the opposite electrode of another organic photovoltaic cell adjacent in the alignment direction and being connected to the opposite electrode;

continuously applying an ink comprising a material of the active layer along the prescribed alignment direction across the plurality of organic photovoltaic cells, when viewed from one side in the thickness direction of the supporting substrate; and

forming the active layer by solidifying the ink applied.

[7] The method for manufacturing a power generator according to above [6], wherein the step of applying ink involves the cap coating method, the spray coating method, or the printing method.

### Effect of the Invention

According to the present invention, the active layer extends integrally along the prescribed alignment direction across the plurality of organic photovoltaic cells connected serially with each other, so that the active layer can be formed with a coating method capable of continuously applying the ink along the alignment direction of a plurality of organic photovoltaic cells, and even by such a coating method, a step of wiping off a part of the once applied ink can be omitted.

In a region different from a region in which the active layer is formed, when viewed from one side in the thickness direction of the supporting substrate, an electrode of one organic photovoltaic cell is connected with an electrode of another organic photovoltaic cell adjacent to the one organic photovoltaic cell, so that even if the active layer extends in the alignment direction across the plurality of organic photovoltaic cells is provided, a plurality of organic photovoltaic cells connected serially with each other can be made.

Particularly, since the power generating region does not become smaller due to the step of wiping off a part of the once applied ink during the formation of the active layer, the distance between the adjacent organic photovoltaic cells can be reduced as far as possible and, then, the power generating region can be made large.

### BRIEF DESCRIPTION OF DRAWINGS

FIG. 1A is a schematic plan view illustrating a power generator.

FIG. 1B is a schematic cross-sectional view for describing a power generator taken along a 1B-1B chain line in FIG. 1A.

FIG. 2A is a schematic plan view for describing steps of manufacturing a power generator.

FIG. 2B is a schematic cross-sectional view for describing steps of manufacturing a power generator taken along a 2B-2B chain line in FIG. 2A.

FIG. 3A is a schematic plan view for describing steps of manufacturing a power generator.

FIG. 3B is a schematic cross-sectional view for describing steps of manufacturing a power generator taken along a 3B-3B chain line in FIG. 3A.

FIG. 4 is a view schematically illustrating a cap coater system.

FIG. 5A is a plan view schematically illustrating a power generator.

FIG. 5B is a schematic cross-sectional view for describing a power generator taken along a 5B-5B chain line in FIG. 5A.

FIG. 6A is a plan view schematically illustrating a power generator.

FIG. 6B is a schematic cross-sectional view for describing a power generator taken along a 6B-6B chain line in FIG. 6A.

FIG. 7A is a plan view schematically illustrating a power generator.

FIG. 7B is a schematic cross-sectional view for describing a power generator taken along a 7B-7B chain line in FIG. 7A.

FIG. 8 is a plan view schematically illustrating a power generator.

FIG. 9A is a plan view schematically illustrating a power generator in which a plurality of organic photovoltaic cells are serially connected with each other.

FIG. 9B is a cross-sectional view schematically illustrating a power generator in which a plurality of organic photovoltaic cells are serially connected with each other taken along a 9B-9B chain line FIG. 9A.

FIG. 10A is a schematic cross-sectional view for describing a step of manufacturing a power generator.

FIG. 10B is a schematic cross-sectional view for describing a step of manufacturing a power generator.

FIG. 10C is a schematic cross-sectional view for describing a step of manufacturing a power generator.

FIG. 10D is a schematic cross-sectional view for describing a step of manufacturing a power generator.

### DESCRIPTION OF EMBODIMENTS

Hereinafter, referring to Drawings, the constitution of the power generator and the method for manufacturing the same are described. Each drawing illustrates the shape, the size, and the arrangement of each component only schematically to such a degree that the present invention can be comprehended. The present invention is not limited by the description below and each component can be accordingly modified as long as not departing from the gist of the present invention. In the embodiments described below, components of the embodiments can be accordingly combined with each other as long as not departing from the gist of the present invention. In each drawing used for the descriptions below, the same constitution elements are indicated by attaching the same letters and an overlapping description of constitution elements may be omitted. In addition, a constitution according to the embodiment of the present invention is not necessarily manufactured or used in an arrangement described in an illustrated example.

1) Constitution of Power Generator

The power generator of the present embodiment can be applied, for example, to a solar cell device and an organic light sensor.

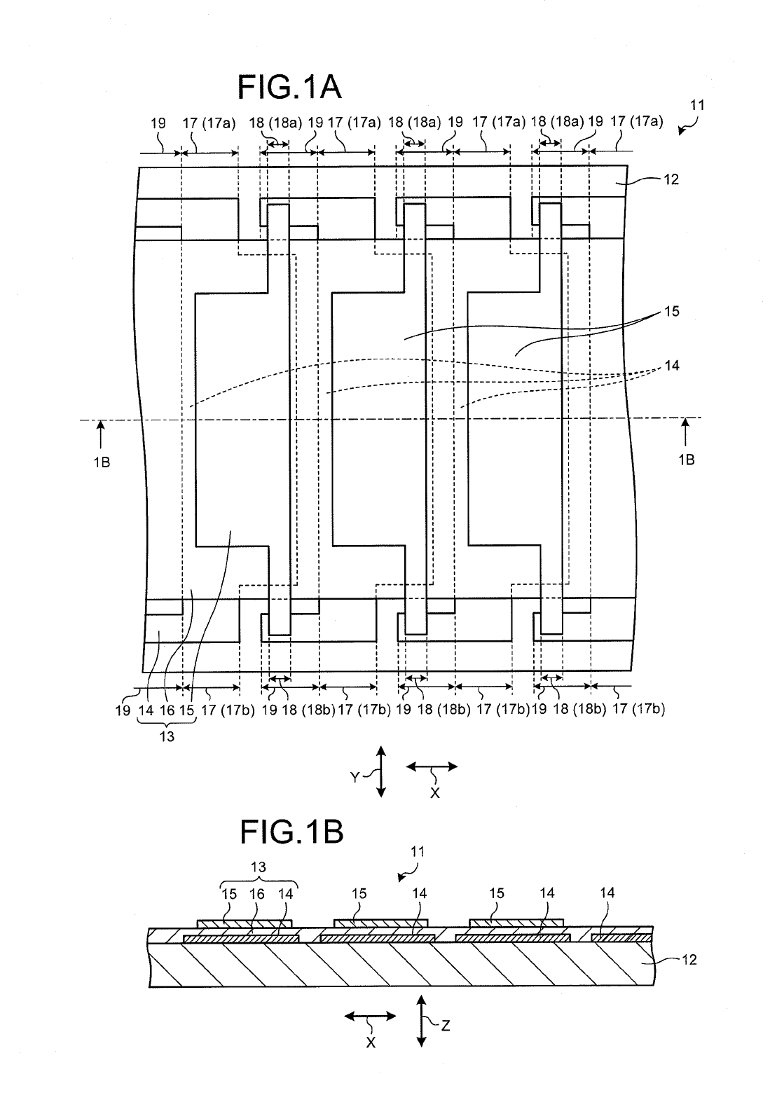

Referring to FIG. 1A and FIG. 1B, a power generator according to a first embodiment of the present invention is described. FIG. 1A is a schematic plan view illustrating a power generator. FIG. 1B is a schematic cross-sectional view for describing a power generator taken along a 1B-1B chain line in FIG. 1A.

A power generator 11 comprises a supporting substrate 12 and a plurality of organic photovoltaic cells 13 provided on the supporting substrate 12 along a prescribed alignment direction X and serially connected with each other.

The prescribed alignment direction X is set in a direction perpendicular to the thickness direction Z of the supporting substrate 12. That is, the alignment direction X is set as a direction parallel to the main surface of the supporting substrate 12.

As illustrated in FIG. 1, in the present embodiment, although a plurality of organic photovoltaic cells 13 are arranged along a prescribed straight line, they may be arranged along a prescribed curved line. When a plurality of organic photovoltaic cells 13 are arranged along a prescribed curved line, the alignment direction X corresponds to a tangential direction of the prescribed curved line.

The number of organic photovoltaic cells 13 provided on the supporting substrate 12 is appropriately set according to the design. Hereinafter, the power generator 11 is described referring to a drawing illustrating three organic photovoltaic cells 13.

A plurality of organic photovoltaic cells 13 individually comprise a pair of electrodes (first electrode 14 and second electrode 15) and a light-emitting layer 16 placed between the pair of electrodes (first electrode 14 and second electrode 15). Any one electrode out of the pair of electrodes (first electrode 14 and second electrode 15) functions as an anode of the organic photovoltaic cell 13 and the other electrode functions as a cathode of the organic photovoltaic cell 13.

Between the first electrode 14 and the second electrode 15, one or more prescribed layers are placed. Between the first electrode 14 and the second electrode 15, at least an active layer 16 is placed as the one or more prescribed layers.

The active layer 16 integrally extends along the alignment direction X across the plurality of organic photovoltaic cells 13. In the present embodiment, in a plurality of organic photovoltaic cells 13 serially connected with each other, the active layer extends along the alignment direction X from an active layer 16 of an organic photovoltaic cell 13 provided at one end (left end in FIG. 1A and FIG. 1B) of the alignment direction X to an active layer 16 of an organic photovoltaic cell 13 provided at the other end (right end in FIG. 1A and FIG. 1B) of the alignment direction X, is continuously integrally formed. When a prescribed layer different from the active layer is placed between the first electrode 14 and the second electrode 15, the prescribed layer may integrally extend along the alignment direction X across the plurality of organic photovoltaic cells 13 or may be formed such that one layer on each cell is parted from another. When the prescribed layer different from the active layer is formed with a coating method, the prescribed layer different from the active layer is preferably integrally extended along the alignment direction X across the plurality of organic photovoltaic cells 13 like the active layer.

Each of the first electrode 14 and the second electrode 15 (a pair of electrodes) has an extending portion (extending portion 17 of first electrode 14 and extending portion 18 of second electrode 15) that extends to protrude from the active layer 16 in a width direction Y perpendicular to both the thickness direction Z of the supporting substrate and the alignment direction X, when viewed from one side in the thickness direction Z of the supporting substrate 12 (hereinafter, also expressed as “in a planar view”). The extending portion 17 of the first electrode 14 is integrally formed with the first electrode 14. The extending portion 18 of the second electrode 15 is integrally formed with the second electrode 15.

A first electrode 14 and a second electrode 15 (a pair of electrodes) making an organic photovoltaic cell 13 do not connect with each other in each organic photovoltaic cell 13, and the extending portion 17 of the first electrode 14 and the extending portion 18 of the second electrode 15 are so arranged that they do not overlap with each other in a planar view. In the present embodiment, the extending portion 17 of the first electrode 14 of each of the organic photovoltaic cells 13 extends to protrude in the width direction Y in a length smaller than the length of the first electrode 14 in the alignment direction X from a left-side end (hereinafter, also referred as “left end”) of the ends of the first electrode 14 on the width direction Y. The extending portion 18 of the second electrode 15 of each of the organic photovoltaic cells 13 extends to protrude in the width direction Y in a length smaller than a length of the second electrode 15 in the alignment direction X from a right-side end (hereinafter, also referred as “right end”) of the ends of the second electrode 15 on the width direction Y. Therefore, the extending portion 17 of the first electrode 14 and the extending portion 18 of the second electrode 15 in each organic photovoltaic cell 13 are so provided that they are not overlapped with each other in a planar view, and are not electrically connected.

At least one electrode among the first electrode 14 and the second electrode 15 (a pair of electrodes) has a connecting portion. This connecting portion extends in the alignment direction X from the extending portion to the opposite electrode of another organic photovoltaic cell adjacent in the alignment direction X to be connected to the opposite electrode. Not only one electrode among the first electrode 14 and the second electrode 15 (a pair of electrodes) has the connecting portion, but also the other electrode out of the first electrode 14 and the second electrode 15 (a pair of electrodes) may have the connecting portion. That is, the other electrode among the first electrode 14 and the second electrode 15 (a pair of electrodes) may also have a connecting portion that extends in the alignment direction X from the extending portion to the one organic photovoltaic electrode of another organic photovoltaic cell adjacent in the alignment direction X to be connected to the one electrode.

In the present embodiment, the first electrode 14 corresponding to one electrode out of the first electrode 14 and the second electrode 15 (a pair of electrodes) has a connecting portion 19. That is, the first electrode 14 of one organic photovoltaic cell comprises the connecting portion 19 that extends from the extending portion 17 of the first electrode 14 to an extending portion 18 of the second electrode 15 of another organic photovoltaic cell 13 arranged adjacent to the one organic photovoltaic cell in the left side thereof. Thus, the connecting portion 19 of the first electrode 14 of one organic photovoltaic cell is overlapped with the extending portion 18 of the second electrode 15 (another electrode) of another organic photovoltaic cell 13 arranged adjacent to the one organic photovoltaic cell in the left side thereof in a planar view to be directly (electrically) connected with the second electrode 15 (another electrode) at the overlapped portion.

The extending portion 17 of the first electrode 14 that extends from the active layer 16 in the width direction Y in a planar view is provided in at least one or the other end side of the width direction Y. The extending portion 17 is preferably provided in the both end sides of the width direction Y. That is, the extending portion 17 of the first electrode 14 or the extending portion 18 of the second electrode 15 comprising preferably a first extending portion 17a of the first electrode 14 or a first extending portion 18a of the second electrode 15 that extend to protrude from the active layer 16 into one side of the width direction in a planar view, and a second extending portion 17b of the first electrode 14 or a second extending portion 18b of the second electrode 15 that extend to protrude from the active layer 16 into the other side of the width direction Y. Containing the extending portion 17 of the first electrode 14 and the extending portion 18 of the second electrode 15 that extend from the active layer 16 into the both sides of the width direction Y in a planar view, the first electrode 14 of the prescribed organic photovoltaic cell 13 and the second electrode 15 of another organic photovoltaic cell 13 adjacent to the prescribed organic photovoltaic cell 13 become connected with each other in the both end sides of the width direction Y.

Furthermore, among a plurality of organic photovoltaic cells 13 that are serially connected with each other, the first electrode 14 of an organic photovoltaic cell 13 arranged in the most left side and the second electrode 15 of an organic photovoltaic cell 13 arranged in the most right side are individually connected with a wiring electrically connected to an external circuit (not illustrated). Herewith, the power is supplied to an external circuit from a plurality of organic photovoltaic cells 13 that are serially connected with each other.

A plurality of organic photovoltaic cells 13 are serially connected by connecting one organic photovoltaic cell 13 with another organic photovoltaic cell 13 adjacent to the one organic photovoltaic cell 13 at the connecting portion 19. In the present embodiment, by comprising the extending portion 17 of the first electrode 14 and the extending portion 18 of the second electrode 15 that extend from the active layer 16 to the both sides of the width direction Y in a planar view, one organic photovoltaic cell 13 and another organic photovoltaic cell 13 adjacent to the one organic photovoltaic cell 13 are serially connected with each other in the both end sides of the width direction Y. Thus, by arranging the connecting portion in the both end sides of the width direction Y, in comparison with a device constitution in which an organic photovoltaic cell 13 is connected with another organic photovoltaic cell 13 only in one end side of the width direction Y, the power consumed at the electrode can be reduced and the power generation efficiency can be enhanced as well.

Hereinafter, the supporting substrate 12 and the layer structure, constitution of each layer, and method for manufacturing each layer of the organic photovoltaic cell 13 are described.

<Supporting Substrate>

As the supporting substrate 12, a substrate that is chemically not changed in a step of manufacturing the organic photovoltaic cell is preferably used and for example, a glass, a plastic, a polymer film, a silicon plate, and a substrate prepared by layering these are used.

<First Electrode and Second Electrode>

For at least one electrode out of the first electrode and the second electrode, a transparent or translucent electrode is used. As the transparent electrode or the translucent electrode, a thin film of a metal oxide, a metal sulfide, and a metal having a high electric conductivity can be used and a thin film having a high light transmittance is preferably used.

As the first electrode and the second electrode, specifically, thin films composed of indium oxide, zinc oxide, tin oxide, ITO, IZO, gold, platinum, silver, and copper are used and among them, thin films composed of ITO, IZO, or tin oxide are preferably used. Examples of the method for manufacturing the transparent electrode or the translucent electrode may include a vacuum vapor deposition method, a sputtering method, an ion plating method, and a plating method. As an example for the transparent electrode or the translucent electrode, an organic transparent conductive film of polyaniline or derivatives thereof, polythiophene or derivatives thereof, or the like may be used.

As the electrode arranged opposite to the above transparent or translucent electrode, the above transparent or translucent electrode or an electrode reflecting light is used. As an example for the electrode material making such an electrode, a metal, metal oxide, and metal sulfide having a work function of 3.0 eV or more are preferred.

<Active Layer>

The active layer making a part of the organic photovoltaic cell of the present invention is provided as a light active layer for converting a light energy to an electric energy and functions as a layer becoming a power generation source of the photovoltaic cell.

Although the active layer is generally provided as one layer per one photovoltaic cell, in order to achieve high power generation efficiency, two or more layers of active layers may be provided per one photovoltaic cell (For example, see Science, (2007), vol. 317, pp. 222 to 225).

The active layer is made with two or more types of semiconductor materials exhibiting p-type semiconductor characteristics and n-type semiconductor characteristics. At least one type among two or more types of semiconductor materials is composed of an organic substance. The active layer is made of (I) a layered body formed by layering a layer made with a p-type semiconductor material and a layer made with an n-type semiconductor material or (II) a mixed layer in which a p-type semiconductor material and an n-type semiconductor material are mixed and integrated. The active layer is preferably made of the mixed layer. This is because the mixed layer can form a wide photocharge separation interface between the p-type semiconductor material and the n-type semiconductor material.

The organic substance having semiconductor characteristics may be a low molecular compound or a macromolecular compound. The organic substance having semiconductor characteristics is, in terms of solubility in a solvent, preferably a macromolecular compound, preferably a macromolecular compound having a polystyrene-equivalent number average molecular weight of 10³ to 10⁸.

The macromolecular compound having p-type semiconductor characteristics is preferably a conjugated macromolecular compound. This is because the conjugated macromolecular compound has high hole electrical conductive characteristics. The conjugated macromolecular compound means (1) a macromolecular compound substantially composed of a structure in which a double bond and a single bond line up alternately, (2) a macromolecular compound substantially composed of a structure in which a double bond and a single bond line up through a nitrogen atom, (3) a macromolecular compound substantially composed of a structure in which a double bond and a single bond line up alternately and a structure in which a double bond and a single bond line up through a nitrogen atom, or the like. Specific examples of the conjugated macromolecular compound may include a macromolecular compound in which: there is contained as a repeating unit, one or more types of diyl groups selected from the group consisting of a fluorenediyl group optionally having a substituent, a benzofluorenediyl group optionally having a substituent, a dibenzofurandiyl group optionally having a substituent, a dibenzothiophenediyl group optionally having a substituent, a carbazolediyl group optionally having a substituent, a thiophenediyl group optionally having a substituent, a furandiyl group optionally having a substituent, a pyrrolediyl group optionally having a substituent, a benzothiadiazolediyl group optionally having a substituent, a phenylenevinylenediyl group optionally having a substituent, a thienylenevinylenediyl group optionally having a substituent, and a triphenylaminediyl group optionally having a substituent; and these repeating units are bonded either directly or through a linking group. In terms of charge transport characteristics, the conjugated macromolecular compound has preferably a thiophene ring structure, more preferably a thiophenediyl group as a repeating unit.

As the material exhibiting n-type semiconductor characteristics, for example, the above conjugated macromolecular compounds, the organic low molecular compounds below, the fullerene derivatives below, and the inorganic substances below can be used.

Examples of such an organic low molecular compound may include oxadiazole derivatives, anthraquinodimethane or derivatives thereof, benzoquinone or derivatives thereof, naphthoquinone or derivatives thereof, anthraquinone or derivatives thereof, tetracyanoanthraquinodimethane or derivatives thereof, fluorenone derivatives, diphenyldicyanoethylene or derivatives thereof, diphenoquinone derivatives, metal complexes of 8-hydroxyquinoline or derivatives thereof, polyquinoline or derivatives thereof, polyquinoxaline or derivatives thereof, and polyfluorene or derivatives thereof.

Examples of the fullerene derivative may include derivatives of C60 fullerene, C70 fullerene, and C84 fullerene.

Examples of the derivative of C 60 fullerene may include the derivatives below.

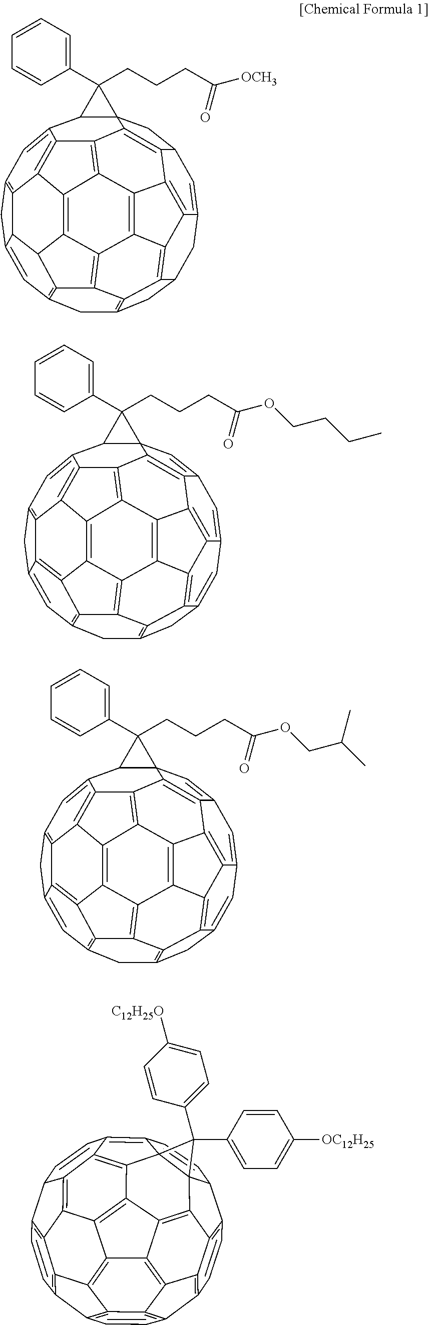

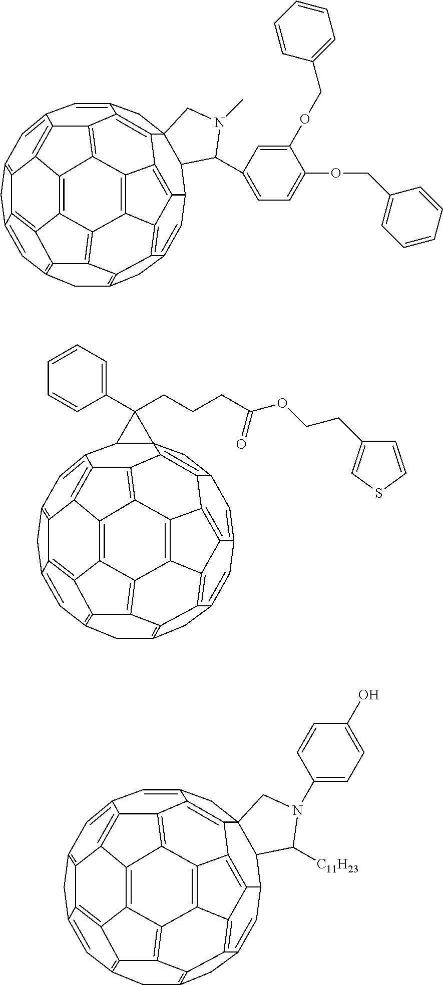

Examples of the derivative of C70 fullerene may include the derivatives below.

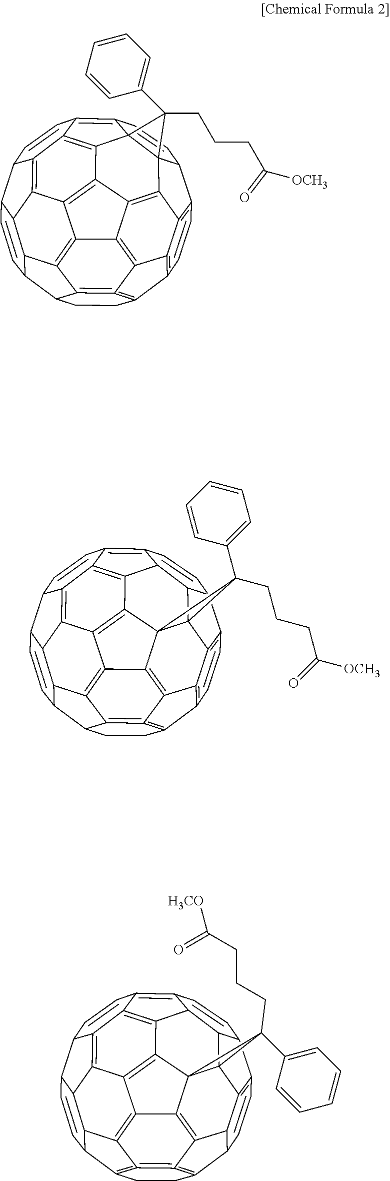

Examples of the inorganic substance having semiconductor characteristics may include a compound semiconductor such as CdSe, and oxide semiconductors such as titanium oxide, zinc oxide, tin oxide, and niobium oxide.

<Intermediate Layer>

In the organic photovoltaic cell, between the electrode and the active layer, if necessary, a prescribed intermediate layer is placed. The intermediate layer is placed, for example, for enhancing power generation characteristics, process durability, and the like. That is, as the intermediate layer, if necessary, layers having characteristics of selectively retrieving an electron or a hole, characteristics of lowering an energy barrier between the electrode and the active layer, film formation properties when a film contained in the layered body is formed, characteristics of reducing a damage against a layer positioned under a film made by film formation, and the like, are provided. Such an intermediate layer is provided between the first electrode and the active layer and/or between the active layer and the second electrode. Examples of the intermediate layer having characteristics of selectively retrieving a hole may include a layer containing poly(ethylenedioxythiophene) (PEDOT). Examples of the intermediate layer having characteristics of selectively retrieving an electron may include a layer containing titanium oxide, a layer containing zinc oxide, and a layer containing tin oxide.

The organic photovoltaic cell is manufactured by layering sequentially the first electrode, one or more intermediate layers provided if necessary, the active layer, one or more intermediate layers provided if necessary, and the second electrode in this order on the substrate.

2) Method for Manufacturing Power Generator

The method for manufacturing the power generator of the present embodiment is a method for manufacturing a power generator comprising a supporting substrate and a plurality of organic photovoltaic cells provided on the supporting substrate along a prescribed alignment direction and serially connected with each other, each of the organic photovoltaic cells comprising a pair of electrodes and an active layer placed between the pair of electrodes, the method comprising the steps of: forming the pair of electrodes having an extending portion that extends to protrude from the active layer into a direction perpendicular to a thickness direction of the supporting substrate and the alignment direction, when viewed from one side in the thickness direction of the supporting substrate, one electrode of the pair of electrodes further having a connecting portion extending in the alignment direction from the extending portion to the opposite electrode of another organic photovoltaic cell adjacent in the alignment direction to be connected to the opposite electrode; continuously applying an ink containing a material of the active layer along the prescribed alignment direction across the plurality of organic photovoltaic cells, when viewed from one side in the thickness direction of the supporting substrate; and forming the active layer by solidifying the ink applied.

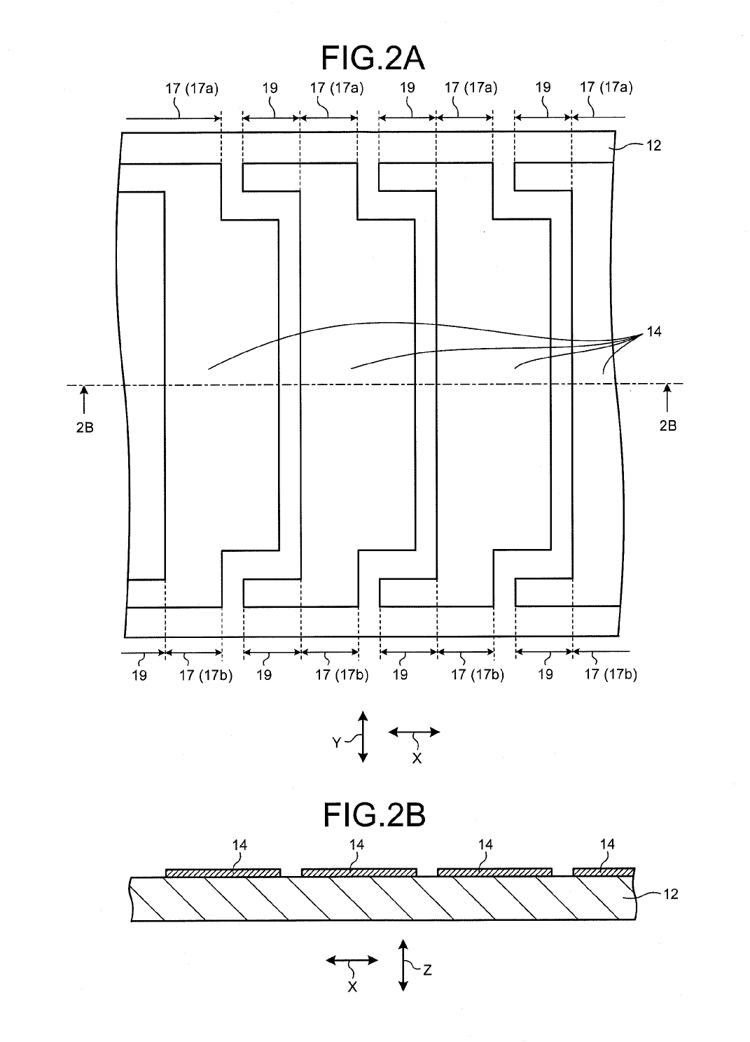

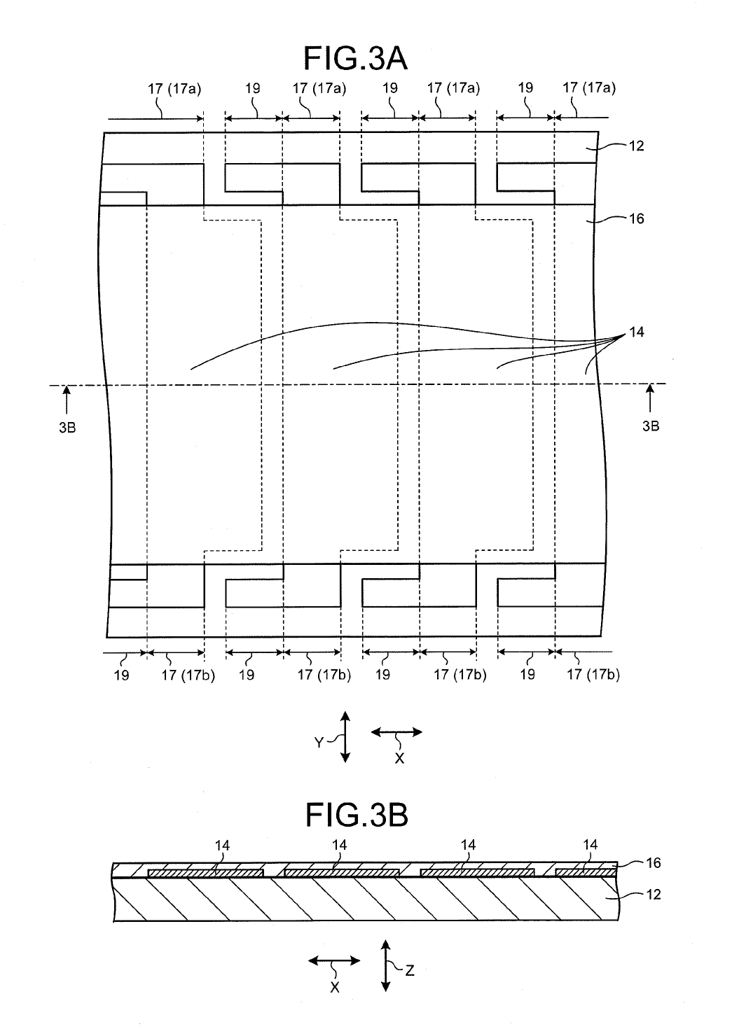

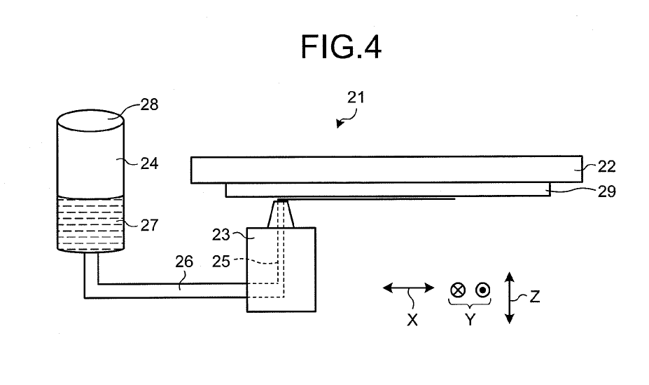

Hereinafter, referring to FIG. 2A, FIG. 2B, FIG. 3A, FIG. 3B, and FIG. 4, the method for manufacturing the power generator is described.

First, the supporting substrate 12 is prepared.

Next, the first electrode 14 is pattern-formed on the supporting substrate 12 as illustrated in FIG. 2A and FIG. 2B. For example, by a sputtering method or a vapor deposition method, a conductive film composed of the above-described material for the anode or the cathode is made by film formation on the supporting substrate 12 and next, by a photolithography step and a patterning step, the conductive film is patterned into a prescribed shape to pattern-form the first electrode 14 into a prescribed shape. By vapor deposition with a mask or the like, only in a prescribed portion, the first electrode 14 may be pattern-formed without performing a photolithography step and a patterning step.

Next, the active layer 16 is formed as illustrated in FIG. 3A and FIG. 3B. An ink containing the above material for the active layer is continuously applied along the alignment direction X across the plurality of organic photovoltaic cells 13 and the applied coating film is solidified, thus forming the active layer.

As described above, between the first electrode 14 and the active layer 16, a prescribed layer different from the active layer 16 may be placed. When the prescribed layer different from the active layer is formed with a coating method, the prescribed layer different from the active layer is preferably formed by the same step of forming the active layer described below. That is, the prescribed layer different from the active layer is preferably formed with continuously applying an ink containing a material for the prescribed layer different from the active layer along the alignment direction X across the plurality of organic photovoltaic cells 13 and by solidifying the applied coating film. Here, when the prescribed layer different from the active layer is formed with a dry method such as a vapor deposition method, the prescribed layer different from the active layer may be selectively formed only on the first electrode 14.

Examples of the method for applying the ink may include a cap coating method, a slit coating method, a spray coating method, a printing method, an inkjet method, and a nozzle printing method. Among these methods, preferred are a cap coating method, a slit coating method, a spray coating method, and a printing method capable of efficiently applying the ink to a large area.

Hereinafter, referring to FIG. 4, as one example of the coating method, a method for applying an ink containing a material for the active layer by a cap coating method is described. FIG. 4 is a view schematically illustrating a cap coater system used for forming the active layer.

Hereinafter, as one example of the embodiment, a method for manufacturing an organic photovoltaic cell comprising “anode/active layer/cathode” is described. For example, in an organic photovoltaic cell having a device structure in which the anode, the active layer, and the cathode are layered in this order on the supporting substrate, the active layer is made to film on the substrate (hereinafter, may be called a object) on which the first electrode as the anode is made to film. Hereinafter, in the present specification, “upper part” and “lower part” mean “upper part in the vertical direction” and “lower part in the vertical direction”, respectively. In the description below of the cap coater system 21, the configuration of a nozzle 23 and the like is described on the assumption of the arrangement when the ink is applied.

The cap coater system 21 comprises mainly a surface plate 22, a nozzle 23, and a tank 24. The surface plate 22 holds the supporting substrate 12 on which the first electrode 14 is formed as an object 29. Examples of the method for holding the object 29 may include vacuum adsorption. The surface plate 22 adsorbs to hold the object 29 with facing to lower a surface to be coated of the object 29 onto which the ink is applied. The surface plate 22 is reciprocated by a displace-driving means (not illustrated) such as a motor and a hydraulic machine in a horizontal direction. A direction in which the surface plate 22 is displaced corresponds to a coating direction, and in the present embodiment, it corresponds to the alignment direction X.

The nozzle 23 has a slit-shaped discharge opening through which the ink is discharged. A short direction of the slit-shaped discharge opening corresponds to the alignment direction X and a longer direction of the slit-shaped discharge opening corresponds to the width direction Y. That is, in the nozzle 23, an opening that extends in the width direction Y is formed. The width of the slit-shaped discharge opening in the short direction is accordingly set according to the property of the ink and the thickness of the coating film. In the cap coating method, the capillary phenomenon is utilized, so that the width of the slit-shaped discharge opening in the short direction is generally around 0.01 mm to 1 mm. The width of the slit-shaped discharge opening in the longer direction is set at a value substantially corresponding to the width of the active layer in the width direction Y.

In a lower part of the slit-shaped discharge opening, a manifold in which the ink is filled is formed. In the nozzle 23, there is formed a slit 25 communicating the slit-shaped discharge opening at the upper end of the nozzle 23 with the manifold. To the manifold, the ink is supplied from the tank 24 and the ink supplied to the manifold is further discharged through the slit 25 and the slit-shaped discharge opening.

The nozzle 23 is supported displaceable in a vertical direction (Z direction) and is displace-driven in the vertical direction by a displace-driving means such as a motor and a hydraulic machine.

The tank 24 holds the ink 27. The ink 27 held in the tank 24 is the ink 27 that is applied to the object 29 and is a liquid containing an organic material for the active layer in the present embodiment. The manifold of the nozzle 23 and the tank 24 communicate with each other through an ink supplying pipe 26. That is, the ink 27 held in the tank 24 is supplied to the manifold through the ink supplying pipe 26 and is further applied onto the object 29 through the slit 25 and the slit-shaped discharge opening. The tank 24 is supported displaceable in the vertical direction and is displace-driven in the vertical direction by a displace-driving means such as a motor and a hydraulic machine. The tank 24 further comprises a liquid level sensor 28 for detecting a liquid level of the ink 27. By the liquid level sensor 28, the height of the liquid level of the ink 27 in the vertical direction is detected. The liquid level sensor 28 is achieved, for example, by an optical sensor or an ultrasonic vibratory sensor.

The ink 27 supplied from the tank 24 to the slit-shaped discharge opening through the ink supplying pipe 26 is extruded through the slit-shaped discharge opening according to a pressure (static pressure) generated according to the height of the liquid level in the tank 24 and a force by capillary phenomenon generated at the slit-shaped discharge opening. The magnitude of the static pressure applied to the coating liquid is determined by a relative difference between the liquid level in the tank 24 and the liquid level in the nozzle 23.

The relative difference can be adjusted by adjusting the position of the tank 24 in the upper-lower direction (vertical direction). Therefore, the amount of the coating liquid extruded through the slit-shaped discharge opening can be controlled by adjusting the position of the tank 24 in the upper-lower direction.

The cap coater system 21 further comprises a controlling portion achieved by a microcomputer or the like. The controlling portion controls the above-described displace-driving means and the like. The controlling portion controls the displace-driving means, so that the positions of the nozzle 23 and the tank 24 in the vertical direction and the displacement of the surface plate 22 in the alignment direction X are controlled. When the ink 27 is applied, the ink 27 is consumed, so that the liquid level of the ink 27 in the tank 24 lowers with time. The lowering of the liquid level is detected by the liquid level sensor 28 and based on the detection result of the liquid level sensor 28, the controlling portion controls the displace-driving means to adjust the position of the tank 24 in the vertical direction. Thus, the height of the ink 27 extruded through the slit-shaped discharge opening can be controlled.

An action of the cap coater system 21 as described above to apply the ink is described.

(Coating Step)

In a state in which the ink 27 discharged through the nozzle 23 is contacted with the object 29, the nozzle 23 and the object 29 are relatively displaced in the prescribed alignment direction X.

Specifically, first, the tank 24 is elevated so that the liquid level of the ink held in the tank 24 becomes higher than the upper end of the nozzle 23 to cause the ink to enter into a state of being discharged through the slit-shaped discharge opening and then, the nozzle 23 is elevated so that the upper end of the nozzle 23 approaches the object 29 to contact the ink discharged through the slit-shaped discharge opening with the object 29.

Next, while maintaining the state in which the ink 27 is contacted with the object 29, the surface plate 22 holding the object 29 is displaced in another direction of the alignment direction X (in FIG. 4, rightward). The surface plate 22 holding the object 29 is displaced by a prescribed distance and then, the displacing of the surface plate 22 is stopped. By this operation, a coating film having substantially the same width as the width of the slit-shaped discharge opening in the longer direction is formed on the surface of the object 29.

In the present embodiment, so as to apply the ink to a region between the first extending portion 17a of the first electrode 14 set in one direction of the width direction Y and the second extending portion 17b of the first electrode 14 set in another direction of the width direction Y, the displacements of the nozzle 23 and the surface plate 22 is controlled.

The distance between the nozzle 23 and the object 29 when the ink 27 is applied is set, for example, at around 0.05 mm to 0.3 mm. In the present embodiment, by displacing the object 29, the ink 27 is applied. The nozzle 23 and the object 29 may be relatively displaced, so that not the object 29, but the nozzle 23 may be displaced in one direction (in FIG. 4, leftward) of the alignment direction X, or both of the nozzle 23 and the object 29 may be displaced.

Then, the nozzle 23 is displaced to a lower part, so that the nozzle 23 is away from the object 29 and the coating film is solidified. For example, when the active layer is formed using a polymerizable compound, by irradiating the coating film with light or by heating the coating film to solidify the coating film, the active layer 16 can be prepared. By removing a solvent contained in the ink 27, the coating film can also be solidified. In this case, by subjecting the coating film to a heating treatment or by leaving the object for a prescribed time, the coating film can be solidified. In this way, the active layer 16 is formed.

As described above, between the second electrode 15 and the active layer 16, a prescribed layer different from the active layer 16 may be placed. When a prescribed layer different from the active layer 16 is formed with a coating method, a prescribed layer different from the active layer 16 is formed on the active layer 16 preferably by the same method as the above-described method for forming the active layer 16. That is, by continuously applying the ink 27 containing a material for a prescribed layer different from the active layer 16 along the alignment direction X across the plurality of organic photovoltaic cells 13 (first electrode 14) and by solidifying the coating film, a prescribed layer different from the active layer 16 is preferably formed. When a prescribed layer different from the active layer 16 is formed with a dry method such as a vapor deposition method, a prescribed layer different from the active layer 16 may be selectively formed only on the first electrode 14 in a planar view.

Next, the second electrode 15 is formed. For example, by vapor deposition with a mask, only in a part (region) where the second electrode 15 should be provided, the above-described material for the anode or the cathode can be selectively made to film to pattern the second electrode 15 on the active layer 16.

With respect to the above-described organic photovoltaic cell 11, in a region protruding in the width direction Y from a region in which the active layer 16 is formed in a planar view, by connecting the first electrode 14 of a prescribed organic photovoltaic cell 13 with the second electrode 15 of another organic photovoltaic cell 13 adjacent to the prescribed organic photovoltaic cell 13, one organic photovoltaic cell 13 and another organic photovoltaic cell 13 that are adjacent to each other are serially connected with each other, so that the first electrode 14 of a prescribed organic photovoltaic cell 13 and the second electrode 15 of another organic photovoltaic cell 13 adjacent to the prescribed organic photovoltaic cell 13 are not necessary to be connected with each other in a region between the prescribed organic photovoltaic cell 13 and the another organic photovoltaic cell 13 that are adjacent to each other. Therefore, in a region between two adjacent organic photovoltaic cells 13, the active layer or the like may be formed and herewith, when the active layer is formed with a coating method, a step of removing an active layer formed in a region between adjacent two organic photovoltaic cells 13 can be omitted. Accordingly, even by a coating method such as a cap coating method that is relatively weak in fine pattern coating, a plurality of organic photovoltaic cells 13 that are serially connected with each other can be easily manufactured.

In addition, when the active layer is formed with the coating method, a step of removing the active layer formed in a region between two adjacent organic photovoltaic cells 13 can be omitted, so that it is not caused that a power generation region is limited to a small region due to the wiping-off of the active layer or the coating liquid for forming the active layer. Therefore, the distance between two adjacent organic photovoltaic cells can be reduced as far as possible, so that the area for the power generation can be made large.

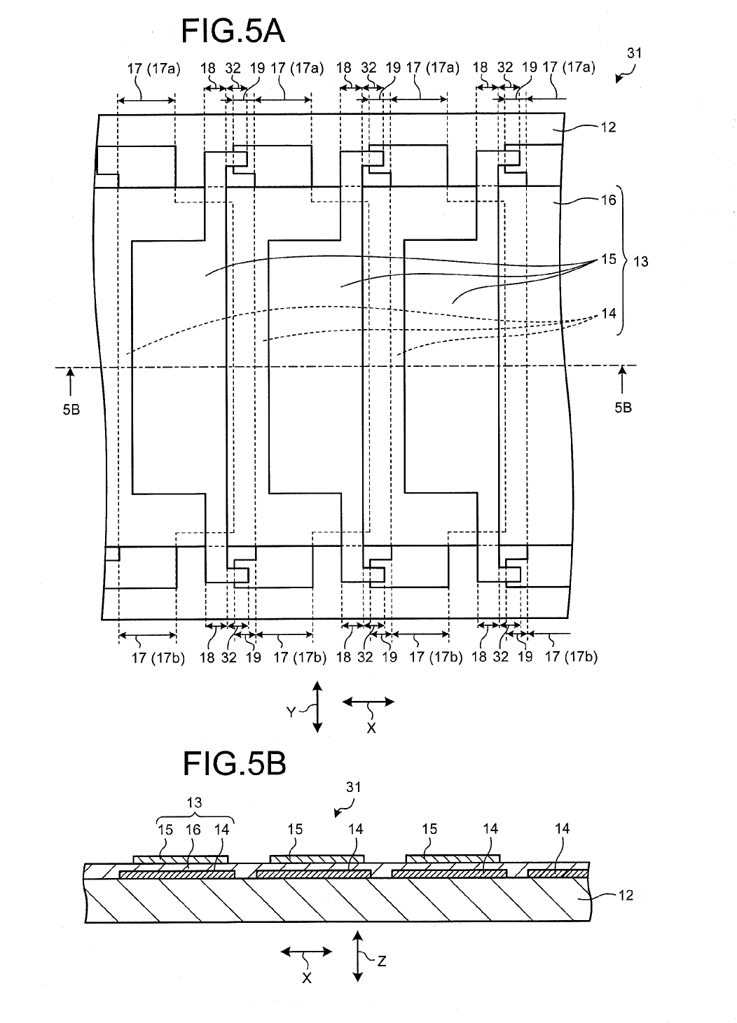

Referring to FIG. 5A and FIG. 5B, a power generator according to the second embodiment is described. FIG. 5A is a plan view schematically illustrating the power generator. FIG. 5B is a schematic cross-sectional view for describing the power generator taken along a 5B-5B chain line in FIG. 5A.

Since a power generator 31 of the present embodiment is different from the power generator 11 of the first embodiment only in the shapes of the first electrode 14 and the second electrode 15, only the first electrode 14 and the second electrode 15 of the present embodiment will be described. To a part corresponding to the component described already in the first embodiment, the same reference numerals as those of the already-described components are attached, and the overlapped descriptions are omitted.

In the present embodiment, in addition to the first electrode 14, the second electrode 15 also has a connecting portion 32. That is, the second electrode 15 of one organic photovoltaic cell 13 has the connecting portion 32 that extends from the extending portion 18 in the alignment direction X to a position at which the connecting portion 32 is overlapped with the connecting portion 19 of the first electrode 14 of another organic photovoltaic cell 13 adjacent to the one organic photovoltaic cell 13 in the alignment direction X each other, and is connected to the second electrode 15.

Accordingly, in a pair of organic photovoltaic cells 13 adjacent to each other in the alignment direction X, the connecting portion 19 extends from the extending portion 17 of the first electrode 14 of an organic photovoltaic cell 13 arranged in a right part to left side, and the connecting portion 32 extends from the extending portion 18 of the second electrode 15 of another organic photovoltaic cell 13 arranged in a left part to right side. These connecting portion 19 of the first electrode 14 and connecting portion 32 of the second electrode 15 are overlapped with each other, so that the first electrode 14 of one organic photovoltaic cell 13 and the second electrode 15 of another organic photovoltaic cell 13 adjacent to the one organic photovoltaic cell 13 are connected with each other.

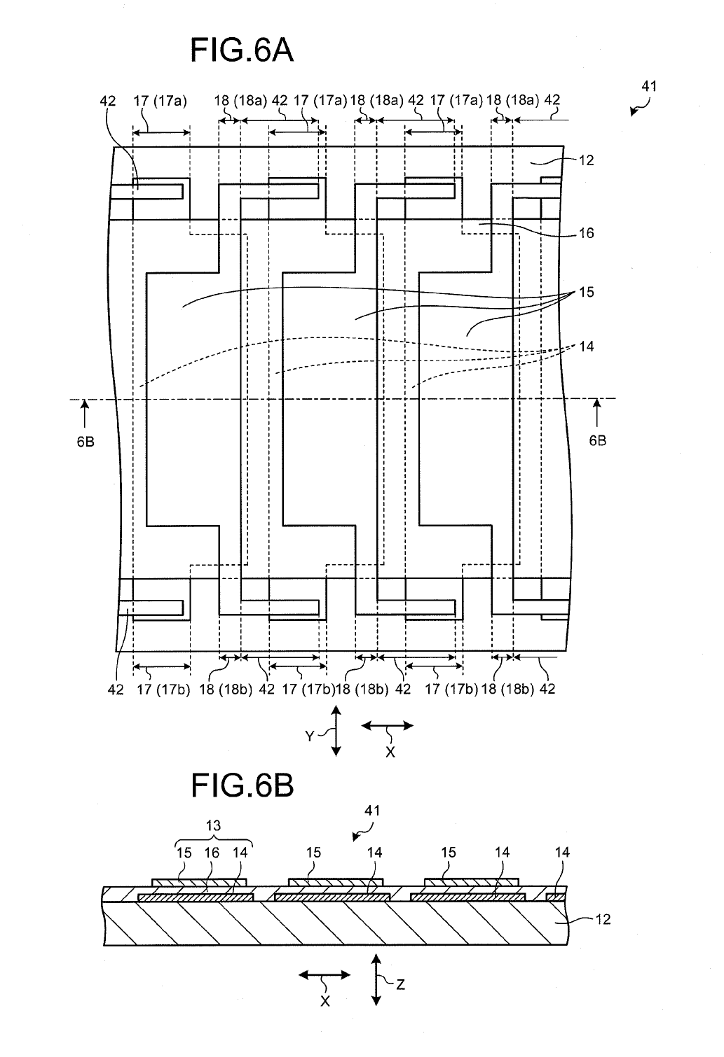

Referring to FIG. 6A and FIG. 6B, a power generator 41 according to a third embodiment of the present invention is described. FIG. 6A is a plan view schematically illustrating the power generator. FIG. 6B is a schematic cross-sectional view for describing the power generator taken along a 6B-6B chain line in FIG. 6A.

Since the power generator 41 of the present embodiment is different from the power generator 11 of the first embodiment only in the shapes of the first electrode 14 and the second electrode 15, only the first electrode 14 and the second electrode 15 of the present embodiment will be described. To a part corresponding to the component described already in the first embodiment, the same reference numerals as those of the already-described components are attached, and the overlapped descriptions are omitted.

In the present embodiment, the first electrode 14 has no connecting portion 19 and the second electrode 15 has a connecting portion 42. That is, the second electrode 15 of one organic photovoltaic cell has the connecting portion 42 that extends from the extending portion 18 in the alignment direction X to the first electrode 14 of another organic photovoltaic cell adjacent to the one organic photovoltaic cell in the alignment direction X, and is overlapped with the extending portion 17 of the first electrode 15 of another organic photovoltaic cell to be connected with the extending portion 17.

In the power generator 11 according to the first embodiment illustrated in FIG. 1A and FIG. 1B, only the first electrode 14 has the connecting portion 19 connected to the extending portion 17 (17a, 17b) and in the power generator 41 according to the third embodiment illustrated in FIG. 6A and FIG. 6B, only the second electrode 15 has the connecting portion 42 connected to the extending portion 18 (18a, 18b). When only any one of the first electrode 14 and the second electrode 15 has the connecting portion, which electrode has the connecting portion may be appropriately selected according to the design. It is preferred that only an electrode having a low sheet resistance among the first electrode 14 and the second electrode 15 (a pair of electrodes) has the connecting portion. That is, when the sheet resistance of the first electrode 14 is lower than the sheet resistance of the second electrode 15, it is preferred that as in the power generator 11 according to the first embodiment illustrated in FIG. 1A and FIG. 1B, only the first electrode 14 has the connecting portion 19. When the sheet resistance of the second electrode 15 is lower than the sheet resistance of the first electrode 14, it is preferred that as in the power generator 41 according to the third embodiment illustrated in FIG. 6A and FIG. 6B, only the second electrode 15 has the connecting portion 42.

Any one of the first electrode 14 and the second electrode 15 is necessary to take light from the outside into the inside of the device, so that any one of them is made of a member exhibiting optical transparency. A member exhibiting optical transparency has generally a sheet resistance higher than that of a conductive member exhibiting optical non-transparency. Therefore, one electrode exhibiting optical transparency out of the first electrode 14 and the second electrode 15 has generally a sheet resistance higher than that of the other electrode out of them. Accordingly, it is generally preferred that only another electrode that is not one electrode exhibiting optical transparency has the connecting portion.

In order to use the power generator, although by the connecting portion made with a conductor, a part of the generated power is consumed, by arranging the connecting portion only in an electrode made with a member having a low sheet resistance, the power consumption caused in the connecting portion can be suppressed and the power generation efficiency can be increased as well.

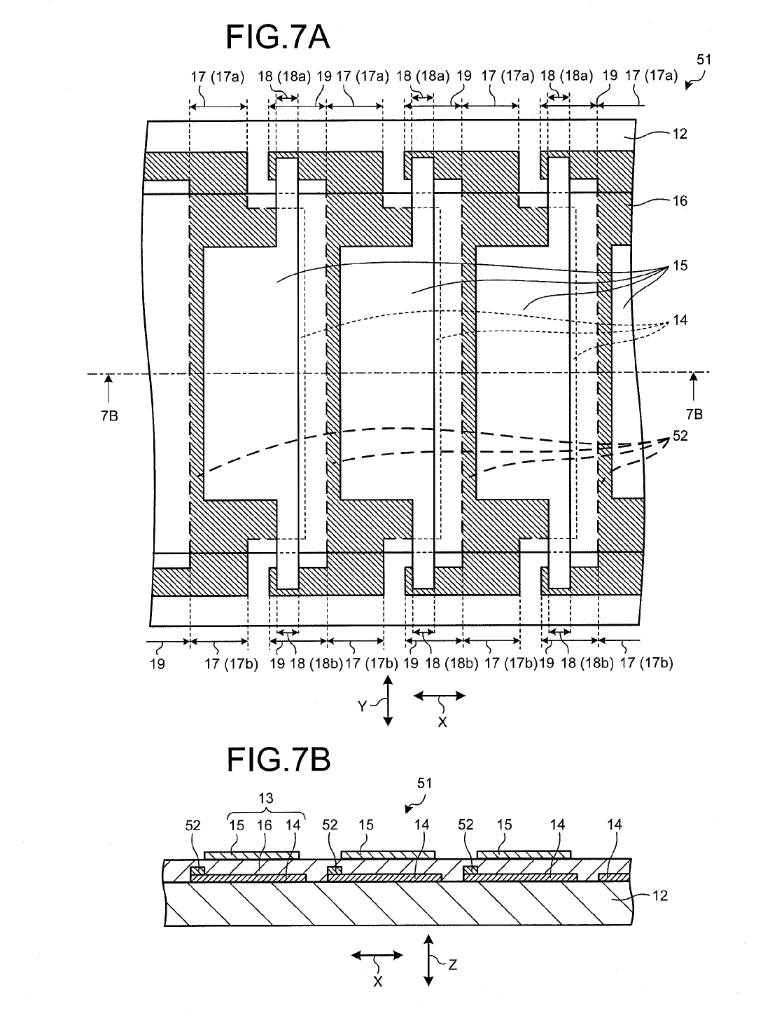

Referring to FIG. 7A and FIG. 7B, a power generator 51 according to a fourth embodiment of the present invention is described. FIG. 7A is a plan view schematically illustrating the power generator. FIG. 7B is a schematic cross-sectional view for describing the power generator taken along a 7B-7B chain line in FIG. 7A.

A power generator 51 of the present embodiment further has an auxiliary electrode 52 that is provided to be in contact with the electrode. Since the power generator 51 according to the present embodiment is different from the power generators of the above embodiments only in the presence or absence of the auxiliary electrode, only the auxiliary electrode will be described. To a part corresponding to the component described already in the above embodiments, the same reference numerals as those of the already-described components are attached, and the overlapped descriptions are omitted. In FIG. 7A, a hatching is applied to a region of the auxiliary electrode.

The auxiliary electrode is provided to be in contact with at least any one of the first electrode 14 and the second electrode 15 (a pair of electrodes). For example, when the auxiliary electrode is provided to be in contact with the first electrode 14 and the second electrode 15, two auxiliary electrodes such as an auxiliary electrode that is provided to be in contact with the first electrode 14 and an auxiliary electrode that is provided to be in contact with the second electrode 15 are provided.

In an example illustrated in FIG. 7A and FIG. 7B, the auxiliary electrode is provided to be in contact with the first electrode 14. In this constitution example, the auxiliary electrode 52 has the extending portion 17 protruding from the active layer 16 into a direction along the width direction Y and the connecting portion 19 that is connected with the extending portion 17 and extends into a direction along to the alignment direction X (in FIG. 7A, to right direction).

The auxiliary electrode 52 is made with a member having a sheet resistance lower than that of the electrode in contact with the auxiliary electrode 52. The auxiliary electrode 52 is preferably provided to be in contact with an electrode having a higher sheet resistance among the first electrode 14 and the second electrode 15 (a pair of electrodes). As described above, any one of the first electrode 14 and the second electrode 15 is made with a member exhibiting optical transparency for taking light from the outside into the inside of the device. Then, any one electrode exhibiting optical transparency has generally a sheet resistance higher than that of the other electrode. Therefore, generally, it is preferred that the auxiliary electrode 52 is provided to be in contact with an electrode exhibiting optical transparency among the first electrode 14 and the second electrode 15. In the power generator 51 according to the present embodiment illustrated in FIG. 7A and FIG. 7B, the auxiliary electrode 52 is provided to be in contact with the first electrode 14 provided as an electrode exhibiting optical transparency.

The auxiliary electrode 52 has a sheet resistance lower than that of the electrode in contact with the auxiliary electrode 52, so that the auxiliary electrode 52 is generally opaque. When an opaque auxiliary electrode 52 is provided to be in contact with an electrode transmitting light, this auxiliary electrode 52 may block off light. Therefore, the auxiliary electrode 52 is preferably provided in a region in which the active layer 16 does not generate power in principle in a planar view.

The active layer 16 can generate power in principle in a region (hereinafter, may called opposite region) in which the first electrode 14 and the second electrode 15 are opposite to each other in a planar view. Therefore, a region in which the active layer 16 does not generate power in principle corresponds to a region remaining after removing the opposite region of the first electrode 14 and the second electrode 15 from all regions in a planar view, that is, a region in which the first electrode 14 and the second electrode 15 are not overlapped with each other in a planar view. Accordingly, the auxiliary electrode 52 is preferably provided in a region excluding the opposite region of the first electrode 14 and the second electrode 15 in a planar view.

By taking into consideration the power generation amount and the voltage drop, the auxiliary electrode 52 may be formed also in the opposite region of the first electrode 14 and the second electrode 15 in a planar view, that is for example, the auxiliary electrode 52 may be formed in a periphery of the opposite region and the opposite region. In a planar view, for example, in the opposite region, an auxiliary electrode 52 is formed in a line shape of lattice shape or stripe shape and an auxiliary electrode 52 formed in the opposite region and an auxiliary electrode 52 formed in a periphery of the opposite region may be connected.

As the material for the auxiliary electrode 52, a material having a high electric conductivity is preferably used. Examples of the material for the auxiliary electrode 52 may include Al, Ag, Cu, Au, and W. As the material for the auxiliary electrode 52, an alloy such as Al—Nd and Ag—Pd—Cu may be used. The thickness of the auxiliary electrode 52 is accordingly set according to the required sheet resistance. The thickness of the auxiliary electrode 52 is, for example, 50 nm to 2,000 nm.

The auxiliary electrode 52 may be made of a single layer or may be a layered body prepared by layering a plurality of layers. The auxiliary electrode 52 may be prepared, for example, for the purpose of enhancing adhesion thereof with the supporting substrate 12 (glass substrate or the like) and the first electrode 14 (ITO thin film or the like) and protecting the surface of a metal from oxygen and moisture, by layering a layer exerting a prescribed function with a thin film composed of a material having a high electric conductivity. As the auxiliary electrode 52, there can be used a layered body having a constitution in which a thin film composed of a material having a high electric conductivity is sandwiched by thin films composed of, for example, Mo, Mo—Nb, Cr, or the like.

In the above-described embodiments, a power generator in which one serial connection is made with a plurality of organic photovoltaic cells is described. However, even to a power generator in which a plurality of serial connections are made with a plurality of organic photovoltaic cells, the present invention can be preferably applied. Even to a power generator made by using a combination of the serial connection and the parallel connection, the present invention can be preferably applied.

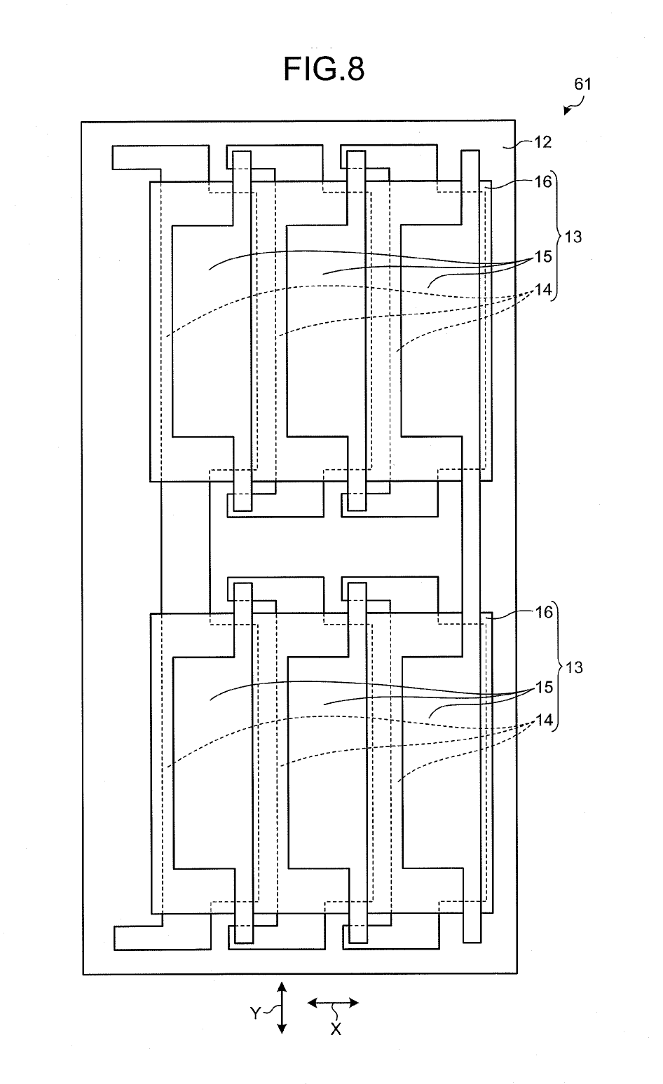

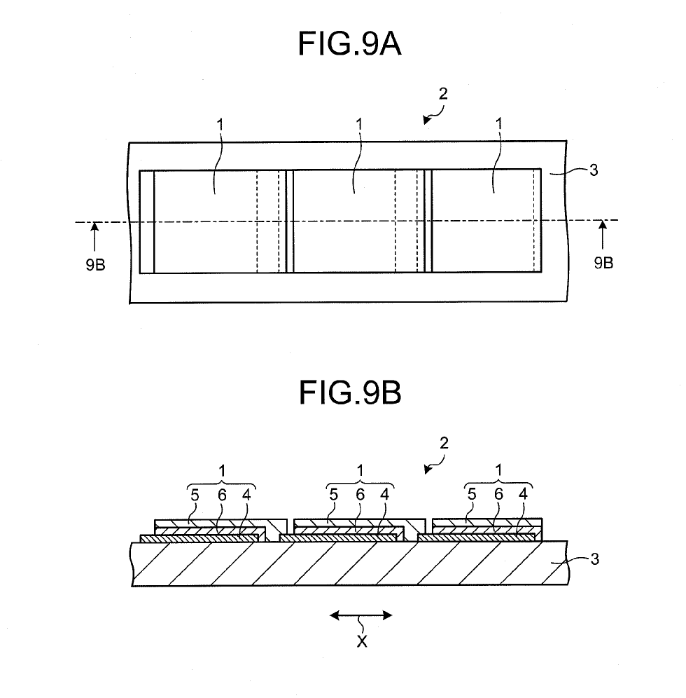

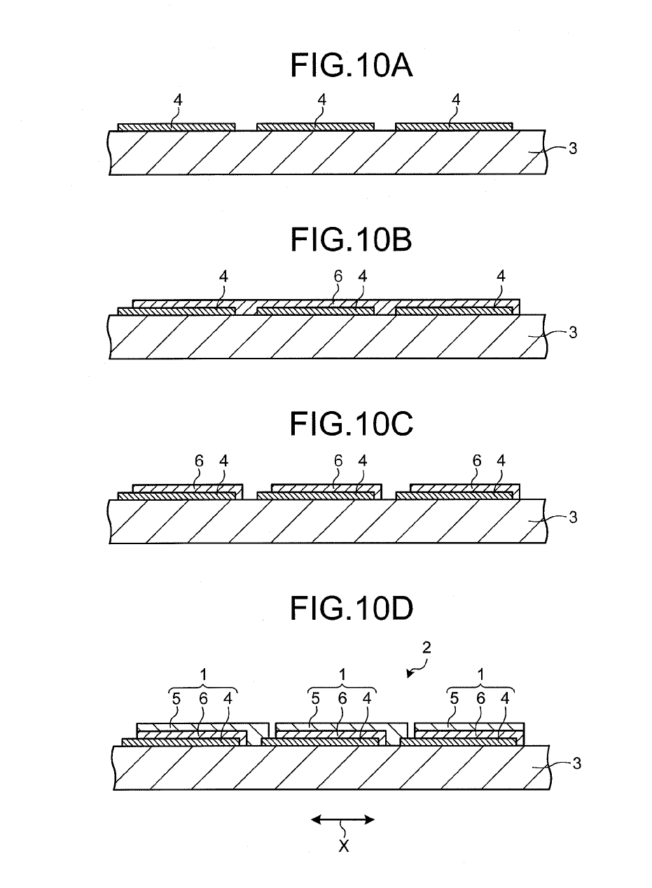

Referring to FIG. 8, a power generator 61 according to a fifth embodiment of the present invention is described. FIG. 8 is a plan view schematically illustrating the power generator.

A power generator 61 of the present embodiment is a power generator having a constitution in which groups of two rows of organic photovoltaic cells that are serially connected are further connected in parallel. A group of organic photovoltaic cells that are serially connected is made, in the illustrated example, by connecting serially three organic photovoltaic cells. Groups of two rows of organic photovoltaic cells that are serially connected with each other are connected in parallel with each other by connecting electrically one ends with each other, that is, by connecting electrically extending portions 18 of the second electrode 15 opposite to each other in a direction along the width direction Y with each other in a right end side of FIG. 8, and by connecting electrically the other ends with each other, that is, by connecting electrically extending portions 17 of the first electrode 14 opposite to each other in a direction along to the width direction Y with each other in a left end side of FIG. 8.

In a power generator in which one serial connection is made with a plurality of organic photovoltaic cells, the more the number of organic photovoltaic cells is, while the higher the generated voltage is, the more the generated current is suppressed. However, by further using a parallel connection in combination, the generated voltage and the generated current can be moderately controlled.

### EXAMPLES

### Synthesis Example 1

### Synthesis of Polymer A

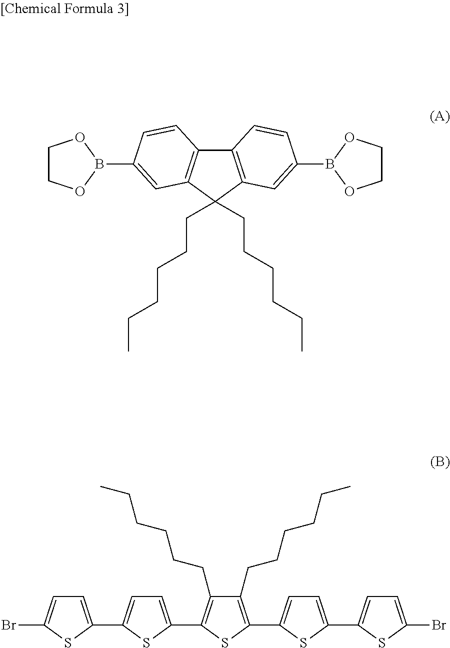 [SMILES: CCCCCCC1(CCCCCC)c2cc(B3OCCO3)ccc2-c2ccc(B3OCCO3)cc21 ; CCCCCCc1c(-c2ccc(-c3ccc(Br)s3)s2)sc(-c2ccc(-c3ccc(Br)s3)s2)c1CCCCCC]

Into a four-neck flask having a volume of 2 L in which an inner atmosphere was purged with argon, a compound (7.928 g, 16.72 mmol) represented by Formula (A) above, a compound (13.00 g, 17.60 mmol) represented by Formula (B) above, methyltrioctylammonium chloride (trade name: aliquat 336; manufactured by Aldrich Corp.; CH₃N[(CH₂)₇CH₃]₃Cl; density at 25° C.: 0.884 g/mL; trade mark of Henkel Corporation) (4.979 g), and 405 mL of toluene were charged and while stirring the resultant reaction mixture, the inside of the system was bubbled with an argon gas for 30 minutes. To the reaction mixture, dichlorobis(triphenylphosphine) palladium (II) (0.02 g) was added and the temperature of the resultant reaction mixture was elevated to 105° C. While stirring the reaction mixture, thereinto, 42.2 mL of a 2 mol/L sodium carbonate aqueous solution was dropped. After the completion of the dropping, the reaction was effected for 5 hours and to the reaction mixture, phenylboronic acid (2.6 g) and 1.8 mL of toluene were added, followed by stirring the resultant reaction mixture at 105° C. for 16 hours. Then, to the reaction mixture, 700 mL of toluene and 200 mL of a 7.5% sodium diethyldithiocarbamate trihydrate aqueous solution were added and the resultant reaction mixture was stirred at 85° C. for 3 hours. An aqueous layer of the reaction mixture was removed and an organic layer thereof was washed with 300 mL of ion-exchanged water of 60° C. twice, with 300 mL of 3% acetic acid of 60° C. once, further with 300 mL of ion-exchanged water of 60° C. three times. The organic layer was passed through a column filled with celite, alumina, and silica and the column was washed with 800 mL of hot toluene. The washed solution was concentrated to 700 mL and the concentrated solution was charged into 2 L of methanol to reprecipitate. The resultant precipitate was filtered to recover a polymer which was washed with 500 mL of methanol, acetone, and methanol. The polymer was vacuum-dried at 50° C. over one night, thus obtaining 12.21 g of a polymer A: pentathienyl-fluorene copolymer represented by the formula below.

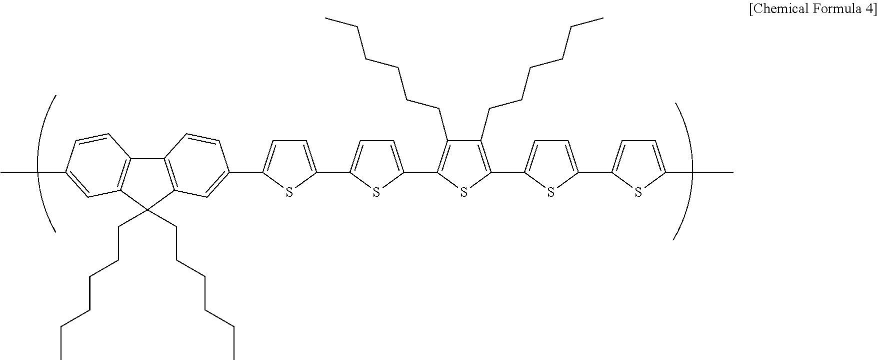

The obtained polymer A had a polystyrene-equivalent number average molecular weight of 5.4×10⁴ and a polystyrene-equivalent weight average molecular weight of 1.1×10⁵.

### Example 1

A power generator having substantially the same constitution as the constitution described already referring to FIG. 1A and FIG. 1B was manufactured. In Example 1, a power generator in which three organic photovoltaic cells were serially connected was manufactured.

The constitution of the organic photovoltaic cell is as follows.

Glass substrate/ITO/PEDOT layer/active layer/BaO/Al

First, a substrate in which an ITO thin film having a thickness of 150 nm was patterned beforehand was prepared. Onto this substrate, a suspension of poly(3,4)ethylenedioxythiophene/polystyrenesulfonic acid (manufactured by Starck; Baytron P) was applied by a spin coating method, thus making a coating film having a thickness of 65 nm by film formation. Next, an unnecessary coating liquid applied onto a periphery portion on a connecting portion or the like was wiped off. Then, the coating film was dried on a hot plate at 200° C. for 10 minutes, thus obtaining a PEDOT layer.

Next, the polymer A corresponding to a p-type semiconductor material and PCBM (manufactured by Frontier Carbon Corporation; trade name: E100, lot. 7B0168-A) which is a fullerene derivative corresponding to an n-type semiconductor material (polymer A: 0.5% by weight, PCBM: 1.5% by weight) were added to orthodichlorobenzene solvent and the resultant mixture was stirred at 70° C. for 2 hours, followed by filtering the mixture with a filter having a pore diameter of 0.2 μm to prepare a coating liquid for an active layer. The coating liquid for an active layer was applied using a cap coating apparatus illustrated in FIG. 4, thus forming an active layer of three organic photovoltaic cells serially connected. After the application of the coating liquid, a wiping-off step was not performed. The obtained active layer had a thickness of 100 nm.

Next, by electron beam vapor deposition, a BaO layer having a thickness of 1.2 nm was formed and further, an Al layer having a thickness of 100 nm was formed to manufacture 16 organic photovoltaic cells.

The power generation region of each of the organic photovoltaic cells was formed in a substantially rectangular shape having a size of 66.0 mm×10.4 mm in a planar view.

Photoelectric conversion of the obtained power generator was measured using a solar simulator (manufactured by Yamashita Denso Corporation; trade name: YSS-80). As the result of measuring a current and a voltage obtained by irradiating the organic photovoltaic cell with light having an irradiance of 100 mW/cm² which was passed through an AM1.5G filter, it was confirmed that all organic photovoltaic cells could generate power.

### Example 2

In Example 2, in the same manner as in Example 1, except that an auxiliary electrode was formed on the anode, a power generator was manufactured. Since the constitution of Example 2 is the same as the constitution of Example 1, except that an auxiliary electrode was provided, only the auxiliary electrode will be described.

The auxiliary electrode was formed on the anode composed of an ITO thin film. The auxiliary electrode was formed on the anode in a region excluding an opposite region of the anode and the cathode. From the ITO thin film side, Mo in a thickness of 50 nm, Al—Nd in a thickness of 800 nm, and Mo in a thickness of 50 nm were deposited in this order each by a vapor deposition method. That is, an auxiliary electrode having a three layers-structure (Mo/Al—Nd/Mo) was formed on the ITO thin film.

Only the ITO thin film as a conductor had a sheet resistance of 10Ω/□ and a layered body in which the auxiliary electrode was layered on the ITO thin film as a conductor had a sheet resistance of 0.38Ω/□. Thus, it was confirmed that by layering with the auxiliary electrode, the sheet resistance can be reduced.

By irradiating the organic photovoltaic cell with light having an irradiance of 100 mW/cm² which was passed through an AM1.5G filter, all organic photovoltaic cells could generate power.

### EXPLANATIONS OF LETTERS OR NUMERALS

1, 13 Organic photovoltaic cell
2, 11, 31, 41, 51, 61 Power generator
3 Supporting substrate
4, 14 First electrode
5, 15 Second electrode
6, 16 Active layer
12 Supporting substrate
17, 18 Extending portion
19, 32, 42 Connecting portion
21 Cap coater system
22 Surface plate
23 Nozzle
24 Tank
25 Slit
26 Ink supplying pipe
27 Ink
28 Liquid level sensor
29 Object
52 Auxiliary electrode

1. A power generator comprising:
a supporting substrate; and
a plurality of organic photovoltaic cells provided on the supporting substrate along a prescribed alignment direction and serially connected with each other, wherein
each of the organic photovoltaic cells comprises a pair of electrodes and an active layer provided between the pair of electrodes,
the active layer extends along the prescribed alignment direction across the plurality of organic photovoltaic cells, when viewed from one side in the thickness direction of the supporting substrate,
each of the pair of electrodes has an extending portion that extends to protrude from the active layer into a direction perpendicular to both the thickness direction of the supporting substrate and the alignment direction, when viewed from one side in the thickness direction of the supporting substrate, and
one electrode of the pair of electrodes further has a connecting portion that extends in the alignment direction from the extending portion to the opposite electrode of another organic photovoltaic cell adjacent in the alignment direction and is connected to the opposite electrode.

2. The power generator according to claim 1, further comprising an auxiliary electrode that is provided to be in contact with one of the pair of electrodes and has a lower sheet resistance than the electrode being in contact within.

3. The power generator according to claim 2, wherein the auxiliary electrode is provided to be in contact with the electrode having a higher sheet resistance out of the pair of electrodes.

4. The power generator according to claim 1, wherein only the electrode having a lower sheet resistance, out of the pair of electrodes, has the connecting portion.

5. The power generator according to claim 1, wherein the extending portion has a first extending portion and a second extending portion, the first extending portion extending to protrude from the active layer into one width direction and the second extending portion extending to protrude from the active layer into the other side of the width direction, each when viewed from one side in the thickness direction of the supporting substrate.

6. A method for manufacturing a power generator comprising a supporting substrate and a plurality of organic photovoltaic cells provided on the supporting substrate along a prescribed alignment direction and serially connected with each other, each of the organic photovoltaic cells comprising a pair of electrodes and an active layer provided between the pair of electrodes, the method comprising the steps of:
forming the pair of electrodes having an extending portion that extends to protrude from the active layer into a direction perpendicular to a thickness direction of the supporting substrate and the alignment direction, when viewed from one side in the thickness direction of the supporting substrate, one electrode of the pair of electrodes further having a connecting portion extending in the alignment direction from the extending portion to the opposite electrode of another organic photovoltaic cell adjacent in the alignment direction and being connected to the opposite electrode;
continuously applying an ink comprising a material of the active layer along the prescribed alignment direction across the plurality of organic photovoltaic cells, when viewed from one side in the thickness direction of the supporting substrate; and
forming the active layer by solidifying the ink applied.

7. The method for manufacturing a power generator according to claim 6, wherein the step of applying ink involves cap coating method, slit coating method, spray coating method, or printing method.
